(19) United States
(12) Patent Application Publication
(10) Pub. No.: US 2006/0121191 A1
(43) Pub. Date: Jun. 8, 2006

(54) Method for coating motor vehicle rims

(76) Inventor: Klaus Tecker, Witten (DE)

Correspondence Address: WILLIAM COLLARD;COLLARD & ROE, P.C., 1077 NORTHERN BOULEVARD, ROSLYN, NY, 11576, US

(21) Appl. No.: 10/527,392

(22) PCT Filed: Sep. 11, 2003
(86) PCT No.: PCT/EP03/10095

§ 371 Date: Sep. 9, 2005

(30) Foreign Application Priority Data
Sep. 13, 2002 (DE) 102 42 555.8

(51) Int. Cl. C23C 16/00

(52) U.S. Cl. 427/248.1

(57) ABSTRACT

The invention relates to a method for coating motor vehicle rims, which consist in particular of a light alloy. According to the method: the rim is first provided with a primer of powder coating or wet lacquer that compensates any irregularities; the primer is then covered with a coating that can be galvanised and the coating is subsequently chromium-plated by galvanisation. The aim of the invention is to omit the application of a plastic coating that can be galvanised to the primer. To achieve this, the coating to be galvanised is a metallic coating, which is applied to the primer by the physical deposition of metal from a gaseous phase (PVD) or by a thermal spraying process.

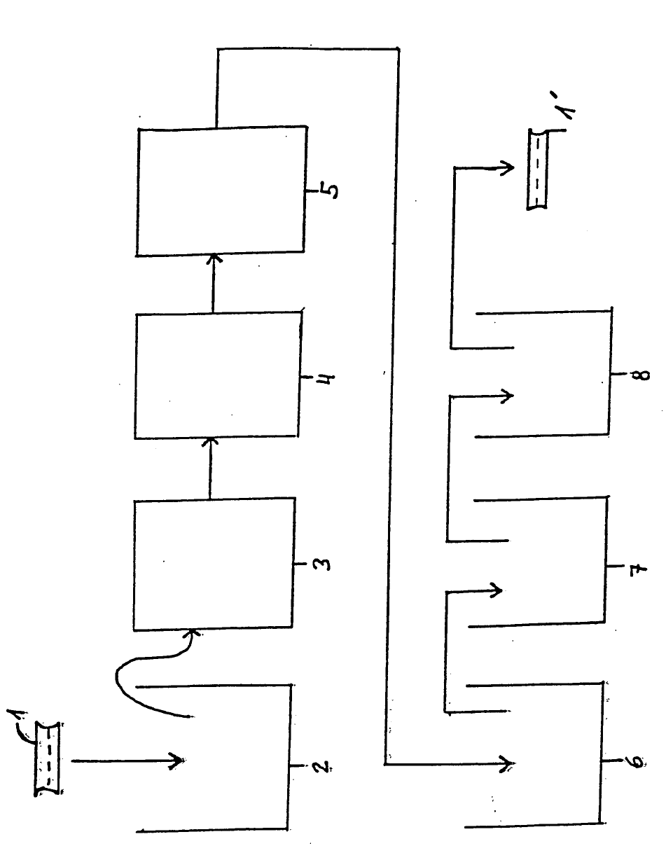

The invention relates to a method for coating motor vehicle rims, particularly made of light alloy, in which the rim is first provided with a primer of powder paint or wet paint that evens out any irregularities, and the primer is covered with a coating that can be galvanized, which is subsequently chrome-plated galvanically.

In a known method of the type stated (see DE 196 21 861 A1), it is known to apply a wet paint to the paint layer that evens out the irregularities, which paint has the character of an electrically conductive galvano-ABS plastic coating after it dries. The surface of this plastic coating is then conditioned for subsequent galvanization, which includes, for example, a plurality of etching and rinsing processes, activation with palladium ions, deactivation, and chemical nickel-plating. The surface conditioned in this manner can then be chrome-plated using the usual galvanization steps, in usual manner, e.g. with the coating sequence flash nickel-nickel-copper-semi-gloss nickel-gloss nickel-chrome.

In this method, the conditioning of the galvano-ABS plastic coating is particularly time-consuming and produces significant amounts of waste water and waste solutions, whose disposal or treatment and recycling is problematic, according to the provisions of the recycling laws.

According to the state of the art, it is also known to chrome-plate motor vehicle rims made of aluminum or aluminum alloys directly. For this purpose, the surface, which is polished to be as smooth as possible, is first freed of the adhering oxides that would hinder the adhesion of the subsequent coatings applied galvanically, using a complicated wet-chemical process. Chrome plating performed directly has the disadvantage here that because of the electrochemical potential difference between the material of the motor vehicle rim, on the one hand, and the metallic coating materials (chrome, nickel, copper), on the other hand, marked electro-corrosion occurs. Such chrome plating therefore flakes off quickly, particularly under the influence of weather conditions, stone impact, road salt, etc. Furthermore, there is the risk that the material of the rim will suffer structural changes during chrome plating, which can make the material become brittle. For this reason, in particular, direct chrome-plating of motor vehicle rims made of light alloy has not been used much, at least in Europe.

According to the state of the art, it is also known (cf. EP 0 632 847) to provide motor vehicle rims with a metallically shiny coating and to cover this metallic coating with a transparent clearcoat. For this purpose, the rim is first provided with a primer of powder paint that evens out the irregularities. Then this paint coating is covered with a high-gloss metal coating of aluminum, chrome, silver, or gold, for example, by means of vapor deposition. Subsequently, this high-gloss metal coating is covered with a clearcoat, which can consist of several layers, if necessary. The coating produced in this manner is clearly cheaper than the chrome-plating of the type stated initially, particularly because it makes do without the expensive plastic coating of a conductive galvano-ABS plastic that can be galvanized, and its conditioning. However, this coating that imitates true chrome-plating never achieves the wear resistance and the gloss of a true chrome plating having an external skin of metallic chrome.

It is therefore the task of the invention to further develop the method of the type stated initially in such a manner that it can do without a plastic coating that can be galvanized, made of galvano-ABS plastic that can be galvanized, and its conditioning, and nevertheless avoids the problems that occur in the chrome-plating of rims made of light alloy.

The object of the invention is a method for coating motor vehicle rims, particularly made of light alloy, in which the rim is first provided with a primer of powder paint or wet paint that evens out any irregularities, and the primer is covered with a coating that can be galvanized, which is subsequently chrome-plated galvanically, whereby this method is characterized in that the coating that can be galvanized is a metal coating that is applied to the primer by means of the physical deposition of metal from the gas phase (PVD) or by means of thermal spraying.

In the case of the method according to the invention, the pre-treatment of the rims by means of polishing and removal of the adhering oxides, which is required for direct chrome-plating of motor vehicle rims, is first of all eliminated, to the greatest possible extent. Instead, the primer is applied in such a thickness that irregularities are evened out, and a completely smooth surface is formed, which adheres to the rim very firmly, particularly if it is fired in. The subsequent coating with metal by means of deposition of the metal from the gas phase (PVD) or by means of thermal spraying also requires relatively little effort. Here, PVD (physical vapor deposition) is understood to mean vapor deposition with metal vapor, cathode atomization (sputtering), or ion plating. All of these methods are suitable for fixing an electrically conductive metal coating on the fired-in primer. The surface of the deposited metal coating is especially smooth and does not need to be polished or subsequently treated in any manner. Subsequently, this electrically conductive metal coating is galvanically chrome-plated, using conventional techniques. The electrically conductive coating of metal used according to the invention is significantly less expensive than the coating of galvano-ABS plastic that was used previously. Above all, galvanization of the metal coating is significantly simpler, in terms of the process, than a surface of galvano-ABS plastic, because the complicated and cost-intensive conditioning of the surface, as explained above, is eliminated. Another significant advantage consists in the fact that the coating produced according to the method according to the invention has a very good temperature resistance. It is practical if the metal coating applied to the primer consists of copper. Copper has the property of conducting electric current particularly well and uniformly, and is therefore particularly well suited for the subsequent galvanization.

An exemplary embodiment of the invention is explained in detail below, using the drawing, which represents a block schematic of the method according to the invention.

In the drawing, the motor vehicle rim is indicated with the reference symbol 1. This motor vehicle rim 1 is first pre-cleaned in a pre-cleaning 2, in order to be freed of adhering contaminants, dirt, grease, chips, etc. From the pre-cleaning 2, the rim 1 subsequently goes to a coating system, in which the rim is coated with a primer (powder paint or wet paint). This coating is subsequently fired in, in a firing oven 4. Subsequently, the rim goes to a coating station 5, in which it is coated with a metal coating, e.g. made of copper, which is deposited from the gas phase, by means of vapor deposition. The coating that is formed by vapor deposition adheres firmly to the primer and is suitable for subsequent galvanization using conventional galvanization methods. The vapor deposition takes place by means of physical deposition of the metal from the gas phase (PVD) or by means of thermal spraying.

Subsequently, the rim 1 that has been provided with the vapor-deposited metal layer goes into three consecutive galvanization baths 6, 7, 8, in which the metal coating is consecutively coated with nickel in galvanization bath 6, with high-gloss nickel in galvanization bath 7, and with chrome in galvanization bath 8. The finished, chrome-plated rim 1′ is discharged at the end of the process.

1. Method for coating motor vehicle rims, particularly made of light alloy, in which the rim is first provided with a primer of powder paint or wet paint that evens out any irregularities, and the primer is covered with a coating that can be galvanized, which is subsequently chrome-plated galvanically, wherein the coating that can be galvanized is an electrically conductive metal coating that is applied to the primer by means of physical deposition of metal from the gas phase (PVD), without any further conditioning of the surface of the primer.

2. Method according to claim 1, wherein the electrically conductive coating that can be galvanized consists of copper.
